(19) United States
(12) Patent Application Publication
(10) Pub. No.: US 2025/0334833 A1
(43) Pub. Date: Oct. 30, 2025

(54) ELECTRONIC DEVICES

(71) Applicant: InnoLux Corporation, Miao-Li County (TW)

(72) Inventors: Tzu-Pin HSIAO, Miao-Li County (TW); Wei-Cheng LEE, Miao-Li County (TW); Ting-Wei LIANG, Miao-Li County (TW); Jiunn-Shyong LIN, Miao-Li County (TW); I-An YAO, Miao-Li County (TW)

(21) Appl. No.: 19/089,427

(22) Filed: Mar. 25, 2025

(30) Foreign Application Priority Data
Apr. 25, 2024 (CN) 202410505130.4

(51) Int. Cl. G02F 1/1335; H05K 1/18

(52) U.S. Cl. CPC G02F 1/133553; G02F 1/133512; H05K 1/189; H05K 2201/10136

(57) ABSTRACT

An electronic device is provided. The electronic device includes a reflective panel; a light-shielding element disposed on a side of the reflective panel away from a viewing side of the electronic device; and a material layer disposed on the side of the reflective panel away from the viewing side of the electronic device. The Young's modulus of the material layer is less than the Young's modulus of the light-shielding element.

### CROSS-REFERENCE TO RELATED APPLICATIONS

The present application claims priority of China Application No. 202410505130.4, filed on April, 25, 2024, which is incorporated by reference herein in its entirety.

### BACKGROUND

### Technical Field

The present disclosure is related to an electronic device, and more particularly it is related to an electronic device including a reflective panel.

### Description of the Related Art

Electronic devices including panels (such as reflective panels) have been widely used in daily life. These electronic devices have the advantage of low power consumption. However, they do not meet expectations in every aspect. Therefore, improvement of the quality and reliability of the electronic devices is still one of the current research topics in the industry.

### SUMMARY

Some embodiments of the present disclosure provide an electronic device. The electronic device includes a reflective panel; a light-shielding element disposed on a side of the reflective panel away from a viewing side of the electronic device; and a material layer disposed on the side of the reflective panel away from the viewing side of the electronic device. The Young's modulus of the material layer is less than the Young's modulus of the light-shielding element.

Some embodiments of the present disclosure provide an electronic device. The electronic device includes a first frame member and a display composite element. The first frame member includes a base plate and a side frame. The side frame is connected to the base plate to form a placement area. The display composite element includes a protective substrate and a reflective panel disposed on a side of the protective substrate. The reflective panel includes a plurality of sub-panels. The reflective panel is disposed in the placement area of the first frame member. The protective substrate is disposed on the first frame member and affixed to the first frame member. There is a first space greater than 0 mm between the display composite element and the base plate.

### BRIEF DESCRIPTION OF THE DRAWINGS

Embodiments of the present disclosure can be best understood from the following detailed description in conjunction with the accompanying drawings. It should be noted that, in accordance with the common practice in the industry, various features are not drawn to scale. In fact, the dimensions of the various elements may be arbitrarily increased or reduced to clearly illustrate the features of the embodiments of the present disclosure. It should also be noted that the drawings illustrate typical embodiments of the present disclosure. The drawings should not be considered as limitation of the present disclosure. The present disclosure may also be applied to other embodiments.

FIG. 1 illustrates a schematic cross-sectional view of an electronic device, according to some embodiments of the present disclosure.

FIG. 2 illustrates a schematic cross-sectional view of an electronic device, according to some embodiments of the present disclosure.

FIG. 3 illustrates a schematic cross-sectional view of an electronic device, according to some embodiments of the present disclosure.

FIG. 4 illustrates a schematic cross-sectional view of an electronic device, according to some embodiments of the present disclosure.

FIG. 5 illustrates a schematic cross-sectional view of an electronic device, according to some embodiments of the present disclosure.

FIG. 6 illustrates a schematic cross-sectional view of an electronic device, according to some embodiments of the present disclosure.

FIG. 7A illustrates a schematic cross-sectional view of an electronic device, according to some embodiments of the present disclosure.

FIG. 7B illustrates a schematic cross-sectional view of an electronic device, according to some embodiments of the present disclosure.

FIG. 7C illustrates a schematic top view of an electronic device, according to some embodiments of the present disclosure.

FIG. 8A illustrates a schematic cross-sectional view of an electronic device, according to some embodiments of the present disclosure.

FIG. 8B illustrates a schematic top view of an electronic device, according to some embodiments of the present disclosure.

FIG. 9 illustrates a schematic cross-sectional view of an electronic device, according to some embodiments of the present disclosure.

FIG. 10 illustrates a schematic cross-sectional view of an electronic device, according to some embodiments of the present disclosure.

FIG. 11 illustrates a partial and schematic cross-sectional view of an electronic device, according to some embodiments of the present disclosure.

FIG. 12 illustrates a partial and schematic cross-sectional view of an electronic device, according to some embodiments of the present disclosure.

FIG. 13 illustrates a partial and schematic cross-sectional view of an electronic device, according to some embodiments of the present disclosure.

FIG. 14 illustrates a partial and schematic cross-sectional view of an electronic device, according to some embodiments of the present disclosure.

### DETAILED DESCRIPTION

The following disclosure provides many different embodiments, or examples, for implementing different features of the described subject matter. Specific examples of elements and arrangements are described below to simplify the present description. These are, of course, merely examples and are not intended to be limiting. For example, a formation of a first feature over or on a second feature in the description that follows may include embodiments in which the first and second features are formed in direct contact, and may also include embodiments in which additional features may be formed between the first and second features, such that the first and second features may not be in direct contact. Furthermore, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When an element or layer is “on” or “connected to” another element or layer, it can be directly on or directly connected to another element or layer, or there is an inserted element or layer between the two (indirect case). In contrast, when an element is “directly on” or “directly connected to” another element or layer, there is no intervening element or layer presented. In addition, the term “electrical connection” or “coupling” includes any direct and indirect means of electrical connection.

It should be understood that the ordinal numbers used in the present disclosure, such as the terms “first”, “second”, “third”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. The claims and the specification may not use the same terms. For example, the first element in the specification may refer to the second element in the claims.

In the following descriptions, terms “about” and “substantially” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. The values given in the present disclosure are approximate. That is, without specifying terms the terms “about” and “substantially”, the meaning of “about” and “substantially” can still be implied.

Some embodiments of the present disclosure are described below. Additional steps or operations may be provided before, during, and/or after the steps or operations described in these embodiments. Some of the steps or operations described may be replaced or deleted in different embodiments. In addition, it should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

In accordance with the embodiments of the present disclosure, the electronic device may include a power module, a semiconductor packaging device, a display device, a backlight device, an antenna device, a touch device, a sensing device, a wearable device, a vehicle device, a battery device, or a tiled device, but it is not limited thereto. The electronic device may be a bendable or flexible electronic device. The display device may be a non-self-luminous display device or a self-luminous display device. The antenna device may be a liquid-crystal type antenna device or a non-liquid-crystal type antenna device. The sensing device may be a sensing device that senses capacitance, light, heat energy or ultrasonic waves, but it is not limited thereto. Furthermore, the electronic device may include, for example, liquid crystals, quantum dots (QDs), fluorescence, phosphorescence, another suitable material, or a combination thereof. The electronic device may include electronic components. The electronic components may include passive components and active components, such as capacitors, resistors, inductors, diodes, transistors, etc. The diode may include a light-emitting diode or a photodiode. The light-emitting diode may include, for example, an organic light-emitting diode (OLED), a mini light-emitting diode (mini LED), a micro light-emitting diode (micro LED) or a quantum dot light-emitting diode (quantum LED), but it is not limited thereto. In accordance with some embodiments, the electronic device may include a panel and/or a backlight module. The panel may include, for example, a liquid-crystal panel or another self-luminous panel, but it is not limited thereto. The tiled device may be, for example, a display tiled device or an antenna tiled device, but it is not limited thereto. It should be understood that the electronic device can be any permutation and combination of the above, but it is not limited thereto.

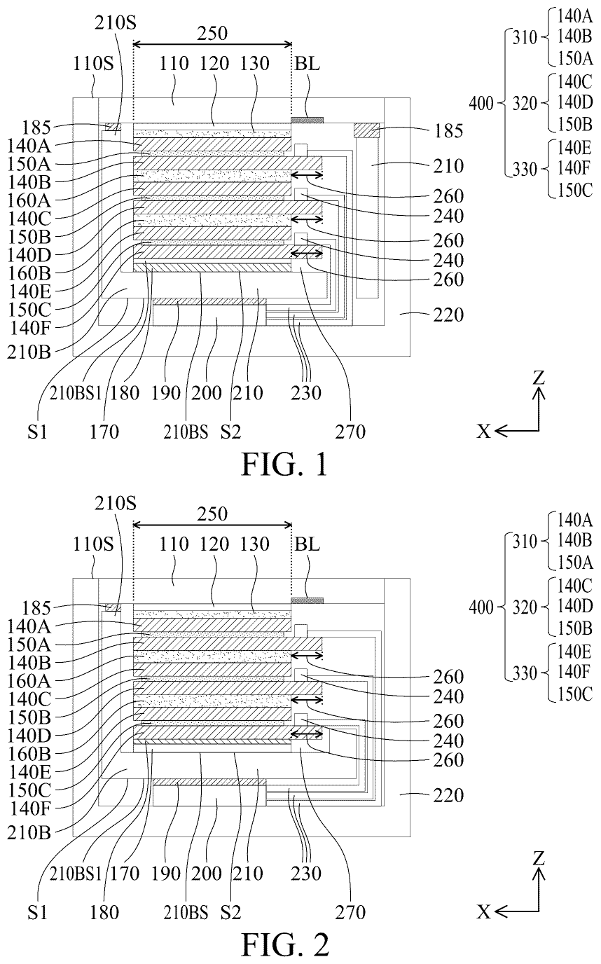

In accordance with the embodiments of the present disclosure, a scanning electron microscope (SEM), an optical microscope (OM), a film thickness profiler (α-step), an ellipsometer or another suitable method may be used to measure the width, thickness or height of each element, or spacing or distance between elements. Specifically, in accordance with some embodiments, a scanning electron microscope may be used to obtain a cross-sectional image including the elements to be measured, and the width, thickness or height of each element, or spacing or distance between elements in the image can be measured. Referring to FIG. 1, FIG. 1 illustrates a schematic cross-sectional view of an electronic device. In some embodiments, the electronic device includes a reflective panel 400. The reflective panel 400 includes a plurality of sub-panels, such as a first sub-panel 310, a second sub-panel 320, and a third sub-panel 330. The number of sub-panels included in the reflective panel 400 may be adjusted according to needs. The first sub-panel 310 includes a first substrate 140A, a second substrate 140B, and a first liquid crystal layer 150A disposed between the first substrate 140A and the second substrate 140B. The second sub-panel 320 includes a third substrate 140C, a fourth substrate 140D, and a second liquid crystal layer 150B disposed between the third substrate 140C and the fourth substrate 140D. The third sub-panel 330 includes a fifth substrate 140E, a sixth substrate 140F, and a third liquid crystal layer 150C disposed between the fifth substrate 140E and the sixth substrate 140F. The first sub-panel 310 and the second sub-panel 320 can be affixed through an attachment member 160A, and the second sub-panel 320 and the third sub-panel 330 can be affixed through an attachment member 160B. In other words, the attachment member 160A is disposed between the first sub-panel 310 and the second sub-panel 320, and the attachment member 160B is disposed between the second sub-panel 310 and the third sub-panel 330.

In some embodiments, the first substrate 140A, the second substrate 140B, the third substrate 140C, the fourth substrate 140D, the fifth substrate 140E, and/or the sixth substrate 140F may include a rigid substrate and a flexible substrate, such as glass, quartz, sapphire, ceramic, other suitable materials, or a combination thereof. The present application is not limited thereto. In some embodiments, the first substrate 140A, the second substrate 140B, the third substrate 140C, the fourth substrate 140D, the fifth substrate 140E, and/or the sixth substrate 140F may include polycarbonate (PC), polyimide (PI), polypropylene (PP), polyethylene terephthalate (PET), polymethylmethacrylate, PMMA), other suitable materials, or a combination thereof. The present application is not limited thereto. In some embodiments, the Young's moduli of the first substrate 140A, the second substrate 140B, the third substrate 140C, the fourth substrate 140D, the fifth substrate 140E, and/or the sixth substrate 140F may be between 1 GPa and 100 GPa (1 GPa≤Young's moduli≤100 GPa), between 5 GPa and 95 GPa (5 GPa≤Young's moduli≤95 GPa), between 10 GPa and 90 GPa (10 GPa≤Young's moduli≤90 GPa), between 15 GPa and 85 GPa (15 GPa≤Young's moduli≤85 GPa), or between 20 GPa and 80 GPa (20 GPa≤Young's moduli≤80 GPa). The present application is not limited thereto.

In some embodiments, the first liquid crystal layer 150A, the second liquid crystal layer 150B, and the third liquid crystal layer 150C may include cholesteric liquid crystal, other suitable liquid crystal materials, or a combination thereof. The present application is not limited thereto. In some embodiments, different electric fields may be applied to the first liquid crystal layer 150A, the second liquid crystal layer 150B, and/or the third liquid crystal layer 150C respectively to change the alignment direction of the liquid crystal molecules, thereby adjusting the display image. For example, the first liquid crystal layer 150A, the second liquid crystal layer 150B, and the third liquid crystal layer 150C may respectively include cholesteric liquid crystal that reflects light of different wavelengths. When the first liquid crystal layer 150A, the second liquid crystal layer 150B, and/or the third liquid crystal layer 150C are respectively arranged in a planar state, the first liquid crystal layer 150A, the second liquid crystal layer 150B, and/or the third liquid crystal layer 150C can reflect light of different wavelengths. For example, the first liquid crystal layer 150A, the second liquid crystal layer 150B, and/or the third liquid crystal layer 150C may respectively reflect blue, green and red light. The present application is not limited thereto. The reflection wavelengths of the first liquid crystal layer 150A, the second liquid crystal layer 150B, and the third liquid crystal layer 150C may be adjusted according to needs.

In some embodiments, the attachment member 160A and/or the attachment member 160B may include optical clear adhesive (OCA), optical clear resin (OCR), other suitable materials, or a combination thereof. The present application is not limited thereto. The attachment member 160A and/or the attachment member 160B may include acrylic (acrylic adhesive) or other suitable materials. In some embodiments, the Young's moduli of the attachment member 160A and/or the attachment member 160B may be between 65 KPa and 400 KPa (65 KPa≤Young's moduli≤400 KPa), between 70 KPa and 380 KPa (70 KPa≤Young's moduli≤380 KPa), or between 75 KPa and 350 KPa (75 KPa≤Young's moduli≤350 KPa). The present application is not limited thereto.

Still referring to FIG. 1, the electronic device includes a sensing element 120 disposed, for example, on the reflective panel 400. The present application is not limited thereto. The electronic device includes a protective substrate 110. The reflective panel 400 is disposed on a side of the protective substrate 110, and the reflective panel 400 includes a plurality of sub-panels (such as the first sub-panel 310, the second sub-panel 320, and the third sub-panel 330). In some embodiments, the sensing element 120 may be disposed between the protective substrate 110 and the reflective panel 400. The present application is not limited thereto. The sensing element 120 may include a single-layer or composite-layer structure. In some embodiments (not shown), the sensing element 120 includes a single layer of a sensing electrode (not shown) or multiple layers of sensing electrodes (not shown). The sensing electrode is, for example, disposed on a surface of the protective substrate 110 (for example, a surface adjacent to the reflective panel 400). In some embodiments, the sensing element 120 may be affixed to the reflective panel 400 through an attachment member 130. The present application is not limited thereto. In some embodiments, the sensing element 120 is used for touch sensing (such as capacitive touch or other touch methods). The present application is not limited thereto.

In some embodiments, the attachment member 130 may include optical clear adhesive (OCA), optical clear resin (OCR), other suitable materials, or a combination thereof. The present application is not limited thereto. In some embodiments, the attachment member 130 may be the same as or different from the attachment 160A or the attachment 160B. In some embodiments, the Young's modulus of the attachment member 130 may be between 200 KPa and 380 KPa (200 KPa≤Young's modulus≤380 KPa), between 220 KPa and 360 KPa (220 KPa≤Young's modulus≤360 KPa), between 240 KPa and 340 KPa (240 KPa≤Young's modulus≤340 KPa), or between 260 KPa and 320 KPa (260 KPa≤Young's modulus≤320 KPa). For example, the Young's modulus of the attachment member 130 may be 230 KPa, 250 KPa, 290 KPa, 310 KPa, or 330 KPa. The present application is not limited thereto.

In some embodiments, the protective substrate 110 may include a rigid substrate, such as a glass substrate, a quartz substrate, a sapphire substrate, and a ceramic substrate. The present application is not limited thereto. In some embodiments, the protective substrate 110 may include polymethylmethacrylate (PMMA), polycarbonate (PC), other suitable materials, or a combination thereof. The present application is not limited thereto. In some embodiments, the Young's modulus of the protective substrate 110 may be between 1 GPa and 80 GPa (1GPa≤Young's modulus≤80 GPa), between 2 GPa and 76 GPa (2 GPa≤Young's modulus≤76 GPa), or between 3 GPa and 72 GPa (3 GPa≤Young's modulus≤72 GPa). When the electronic device does not include the protective substrate 110, an acting force or reacting force from a finger or other object (such as a stylus) applied on the electronic device may easily cause the thickness of the first liquid crystal layer 150A, the second liquid crystal layer 150B, and/or the third liquid crystal layer 150C in the electronic device to change. That is, the cell gap changes. This affects the arrangement of liquid crystal molecules in the liquid crystal layers, resulting in uneven brightness or mura of the display panel. Through the protective substrate 110, the impact of the acting force or reacting force on the liquid crystal layers can be reduced, and the occurrence of mura can be reduced. The larger the thickness of the protective substrate 110, the higher the pressure resistance of the electronic device. However, a larger thickness of the protective substrate 110 is not conducive to the thinning of the electronic device, or is not conducive to the functional operation of the sensing element 120.

Still referring to FIG. 1, the electronic device includes a light-shielding element 170 and a material layer 180. The light-shielding element 170 is disposed on a side of the reflective panel 400 away from a viewing side 110S of the electronic device, and the material layer 180 is disposed on the side of the reflective panel 400 away from the viewing side 110S of the electronic device. In some embodiments, the light-shielding element 170 is disposed between the reflective panel 400 and the material layer 180. The present application is not limited thereto. The light-shielding element 170 may include a light-shielding substrate or a light-shielding material formed on a substrate. The light-shielding material may include a black absorbing layer, such as black photoresist, black printing ink, black resin, black organic material, black inorganic material, black ink, black tape or other suitable color light-shielding materials. The present application is not limited thereto. In some embodiments, the Young's modulus of the light-shielding element 170 may be between 1000 MPa and 8000 MPa (1000 MPa≤Young's modulus≤8000 MPa), between 1500 MPa and 7500 MPa (1500 MPa≤Young's modulus≤7500 MPa), between 2000 MPa and 7000 MPa (2000 MPa≤Young's modulus≤7000 MPa), between 2500 MPa and 6500 MPa (2500 MPa≤Young's modulus≤6500 MPa), or between 3000 MPa and 6000 MPa (3000 MPa≤Young's modulus≤6000 MPa). The present application is not limited thereto.

In some embodiments, the material layer 180 may include a soft material. The material layer 180 may include sponge, soft plastic, foam, other suitable materials, or a combination thereof. The present application is not limited thereto. In some embodiments, the Young's modulus of the material layer 180 may be between 20 KPa and 350 KPa (20 KPa≤Young's modulus≤350 KPa), between 25 KPa and 320 KPa (25 KPa≤Young's modulus≤320 KPa), between 30 KPa and 310 KPa (30 KPa≤Young's modulus≤310 KPa), between 40 KPa and 280 KPa (40 KPa≤Young's modulus≤280 KPa), or between 45 KPa and 260 KPa (45 KPa≤Young's modulus≤260 KPa). The present application is not limited thereto. Through the disposition of the material layer 180 on the side of the reflective panel 400 away from the viewing side 110S of the electronic device, and the Young's modulus of the material layer 180 less than the Young's moduli of the protective substrate 110, the first substrate 140A, the second substrate 140B, the third substrate 140C, the fourth substrate 140D, the fifth substrate 140E, the sixth substrate 140F, the attachment member 160A, the attachment member 160B, and/or the light-shielding element 170, a reacting force of pressing can be dispersed to reduce the impact of the reacting force on the reflective panel 400 or reduce the occurrence of mura.

Still referring to FIG. 1, the electronic device includes a first frame member 210 and/or a second frame member 220. The electronic device includes a circuit element 200 located between the first frame member 210 and the second frame member 220. The first frame member 210 may be affixed to the protective substrate 110 through a patterned attachment member 185. The present application is not limited thereto. The circuit element 200 may be affixed to the first frame member 210 through an attachment member 190. The present application is not limited thereto. The circuit element 200 may be electrically connected to a plurality of electronic components 240 (such as driving chips) through a plurality of flexible circuit boards 230. A plurality of electronic components 240 (such as driving chips) are respectively disposed on peripheral circuit bonding areas of the second substrate 140B, the fourth substrate 140D, and the sixth substrate 140F (referring to the subsequent description). The circuit element 200 transmits signals to different sub-panels (such as the first sub-panel 310, the second sub-panel 320, and the third sub-panel 330) through a plurality of flexible circuit boards 230.

In some embodiments, the material of the first frame member 210 may include metal, plastic, ceramic, other suitable materials, or a combination thereof. The present application is not limited thereto. In some embodiments, the material of the second frame member 220 may include metal, plastic, ceramic, other suitable materials, or a combination thereof. The present application is not limited thereto. In some embodiments, the material of the first frame member 210 is the same as or different from the material of the second frame member 220. In some embodiments, the first frame member 210 and the second frame member 220 may be affixed through mechanical components (not shown, such as screws or other components) or attachments (not shown). The present application is not limited thereto.

In some embodiments, the circuit element 200 may include a rigid circuit board or a flexible circuit board, such as a printed circuit board (PCB). The present application is not limited thereto. The circuit element 200 may include various electronic components or control components. In some embodiments, the circuit element 200 may include an active or passive driving circuit. The present application is not limited thereto.

In some embodiments, the attachment member 185 is disposed on a portion of the first frame member 210 to affix the first frame member 210 and the protective substrate 110. The attachment member 185 may include light-curing adhesive, heat-curing adhesive, double-sided tape, buffer adhesive (such as foam tape), other suitable materials or a combination thereof. The present application is not limited thereto. In some embodiments, the attachment member 185 includes, for example, a loop attachment member. In some embodiments, the attachment 185 member includes, for example, multiple segmented attachment members.

In some embodiments, the circuit element 200 may be affixed to the first frame member 210 through the attachment member 190. For example, the circuit element 200 may be affixed to the outside of the first frame member 210 (the side away from the reflective panel 400) through the attachment member 190. The attachment member 190 may include light-curing adhesive, heat-curing adhesive, double-sided tape, other suitable materials, or a combination thereof. The present application is not limited thereto. In some embodiments, the area of attachment member 190 may be smaller than the area of circuit element 200.

In some embodiments (not shown), the circuit element 200 and the first frame member 210 may be affixed through mechanical components (not shown, such as screws or other components).

Referring to FIG. 2, FIG. 2 illustrates a schematic cross-sectional view of an electronic device. The embodiment shown in FIG. 2 is different from the embodiment shown in FIG. 1 in that the material layer 180 is disposed between the reflective panel 400 and the light-shielding element 170. In the embodiment of FIG. 1, the material layer 180 is disposed between the light-shielding element 170 and the first frame member 210. In the embodiment of FIG. 2, the material layer 180 is disposed on the light-shielding element 170, or the light-shielding element 170 is disposed between the material layer 180 and the first frame member 210. When the material layer 180 is disposed between the reflective panel 400 and the first frame member 210, or the material layer 180 is disposed on the side of the reflective panel 400 away from the viewing side 110S, the material layer 180 may include a transparent material or a non-transparent material.

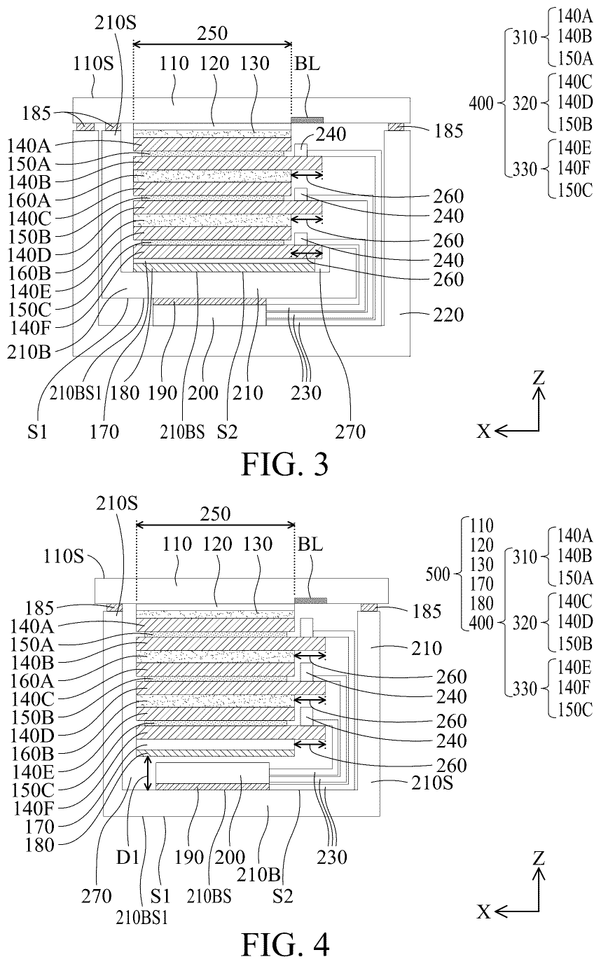

Referring to FIG. 3, FIG. 3 illustrates a schematic cross-sectional view of an electronic device. The embodiment shown in FIG. 3 is different from the embodiment shown in FIG. 1 in that the light-shielding element 170 and/or the material layer 180 may extend from an active area 250 of the reflective panel 400 to a peripheral circuit bonding area 260 of the reflective panel 400. Each sub-panel (such as the first sub-panel 310, the second sub-panel 320, and the third sub-panel 330) of the reflective panel 400 may include the active area 250 and the peripheral circuit bonding area 260. For example, the active area 250 may include a display area, a touch area, and/or a sensing area. The present application is not limited thereto. As shown in FIG. 3, the first substrate 140A and the second substrate 140B of the first sub-panel 310 are disposed opposite to each other. The area (or size) of the upper or lower surface of the second substrate 140B is greater than the area (or size) of the upper or lower surface of the first substrate 140A. The second substrate 140B has the peripheral circuit bonding area 260 adjacent to at least one side of the active area 250. In the top-view direction Z (that is, the normal direction of the upper surface of the first substrate 140A), a portion of the second substrate 140B overlaps the first substrate 140A, and another portion of the second substrate 140B does not overlap the first substrate 140A. The area where the second substrate 140B overlaps the first substrate 140A may be defined as the active area 250. The area of the second substrate 140B that protrudes from or does not overlap the first substrate 140A may be defined as the peripheral circuit bonding area 260.

Similarly, the third substrate 140C and the fourth substrate 140D of the second sub-panel 320 are disposed opposite to each other. The area (or size) of the upper or lower surface of the fourth substrate 140D is greater than the area (or size) of the upper or lower surface of the third substrate 140C. The fourth substrate 140D has the peripheral circuit bonding area 260 adjacent to at least one side of the active area 250. In the top-view direction Z, a portion of the fourth substrate 140D overlaps the third substrate 140C, and another portion of the fourth substrate 140D does not overlap the third substrate 140C. The area where the fourth substrate 140D overlaps the third substrate 140C may be defined as the active area 250. The area of the fourth substrate 140D that protrudes from or does not overlap the third substrate 140C may be defined as the peripheral circuit bonding area 260.

Similarly, the fifth substrate 140E and the sixth substrate 140F of the third sub-panel 330 are disposed opposite to each other. The area (or size) of the upper or lower surface of the sixth substrate 140F is greater than the area (or size) of the upper or lower surface of the fifth substrate 140E. The sixth substrate 140F has the peripheral circuit bonding area 260 adjacent to at least one side of the active area 250. In the top-view direction Z, a portion of the sixth substrate 140F overlaps the fifth substrate 140E, and another portion of the sixth substrate 140F does not overlap the fifth substrate 140E. The area where the sixth substrate 140F overlaps the fifth substrate 140E may be defined as the active area 250. The area of the sixth substrate 140F that protrudes from or does not overlap the fifth substrate 140E may be defined as the peripheral circuit bonding area 260.

According to some embodiments, in the top view direction Z, the material layer 180 and/or the light-shielding element 170 overlaps a plurality of electronic components 240. In some embodiments, the light-shielding material BL may be disposed on a surface of the protective substrate 110 and adjacent to the reflective panel 400. In the top view direction Z, the light-shielding material BL overlaps the peripheral circuit bonding area 260. In some embodiments (not shown), the light-shielding material BL may also partially overlap the active area 250, the sensing element 120 and/or the attachment member 130. The present application is not limited thereto. In some embodiments, in the top view direction Z, the material layer 180 and/or the light-shielding element 170 overlaps the light-shielding material BL.

As shown in FIG. 3, the electronic device includes the light-shielding element 170 disposed on the side of the reflective panel 400 away from the viewing side 110S of the electronic device. The material layer 180 in the electronic device may be disposed on the side of the reflective panel 400 away from the viewing side 110S of the electronic device. According to some embodiments, the Young's modulus of the material layer 180 is less than the Young's modulus of the light-shielding element 170. The Young's modulus of the material layer 180 may refer to the description above.

According to some embodiments, as shown in FIG. 3, the light-shielding element 170 is disposed between the reflective panel 400 and the material layer 180. According to some embodiments, the light-shielding element 170 and/or the material layer 180 may extend from the active area 250 to the peripheral circuit bonding area 260. In the top view direction Z, the material layer 180 overlaps the active area 250 and the peripheral circuit bonding area 260 of the reflective panel 400. Similarly, referring to FIG. 2, the material layer 180 and/or the light-shielding element 170 may also selectively extend from the active area 250 to the peripheral circuit bonding area 260 (not shown). According to some embodiments, when the material layer 180 extends to the peripheral circuit bonding area 260, the multiple sub-panels may be aligned and affixed to each other before the material layer 180 is disposed, so as to reduce the impact of the material layer 180 on the alignment and affixing process of the multiple sub-panels. According to some embodiments, considering the alignment accuracy of multiple sub-panels, the Young's modulus of the material layer 180 is, for example, less than the Young's modulus of the attachment member 160A and/or the attachment member 160B. That is, the Young's modulus of the attachment member 160A and/or the attachment member 160B is, for example, greater than the Young's modulus of the material layer 180. Through the design above, the possibility of offset during alignment and affixing of the multiple sub-panels is reduced.

As shown in FIG. 3, when the area (or size) of the upper surface or the lower surface of the protective substrate 110 is, for example, larger than the areas (or sizes) of the upper surfaces or lower surfaces of the sub-panels (such as the first sub-panel 310, the second sub-panel 320, and the third sub-panel 330), the protective substrate 110 may be selectively affixed to the first frame member 210 and/or the second frame member 220 through the attachment member 185, or the protective substrate 110 may be affixed to the second frame 220 through other means (such as mechanical components). The first frame member 210, the reflective panel 400, the circuit element 200, and a plurality of flexible circuit boards 230 may be disposed in the second frame 220.

Referring to FIG. 4, FIG. 4 illustrates a schematic cross-sectional view of an electronic device. The electronic device includes a first frame member 210. The first frame member 210 includes a base plate 210B and a side frame 210S. The side frame 210S is connected to the base plate 210B to form a receiving area 270. The embodiment shown in FIG. 4 is different from the embodiment shown in FIG. 1 in that the electronic device may not include the second frame member 220, and the circuit element 200 may be disposed or affixed in the receiving area 270 of the first frame member 210 through, for example, the attachment member 190. In some embodiments, the material of the attachment member 190 may refer to the description above. In other embodiments (not shown), the attachment member 190 may be omitted. The circuit element 200 may be affixed in the receiving area 270 of the first frame member 210 through mechanical components (such as screws or other components). In some embodiments (not shown in FIG. 4), the circuit element 200 may be or not be in contact with material layer 180. In some embodiments, the circuit element 200 may be disposed on the side S2 of the bottom plate 210B of the first frame member 210 adjacent to the reflective panel 400, and overlap the reflective panel 400. In some embodiments, the electronic device includes a plurality of flexible circuit boards 230. A plurality of flexible circuit boards 230 are electrically connected to a plurality of sub-panels (such as the first sub-panel 310, the second sub-panel 320, and the third sub-panel 330), respectively. A plurality of flexible circuit boards 230 are bent under the reflective panel 400 and electrically connected to the circuit element 200. In some embodiments, the reflective panel 400 is disposed in the receiving area 270 of the first frame member 210, and the protective substrate 110 is disposed on the first frame member 210 and affixed with the first frame member 210. As shown in FIG. 4, there is a space D1 between a display composite element 500 and the base plate 210B of the first frame member 210, and the space D1 is greater than 0 mm.

According to the embodiment of the present application (FIG. 4), in the top view direction Z (or the normal direction of the upper surface of the first substrate 140A), the space D1 refers to the average space between the bottom surface of the display composite element 500 and the inner surface 210BS of the base plate 210B of the first frame member 210 at any three places.

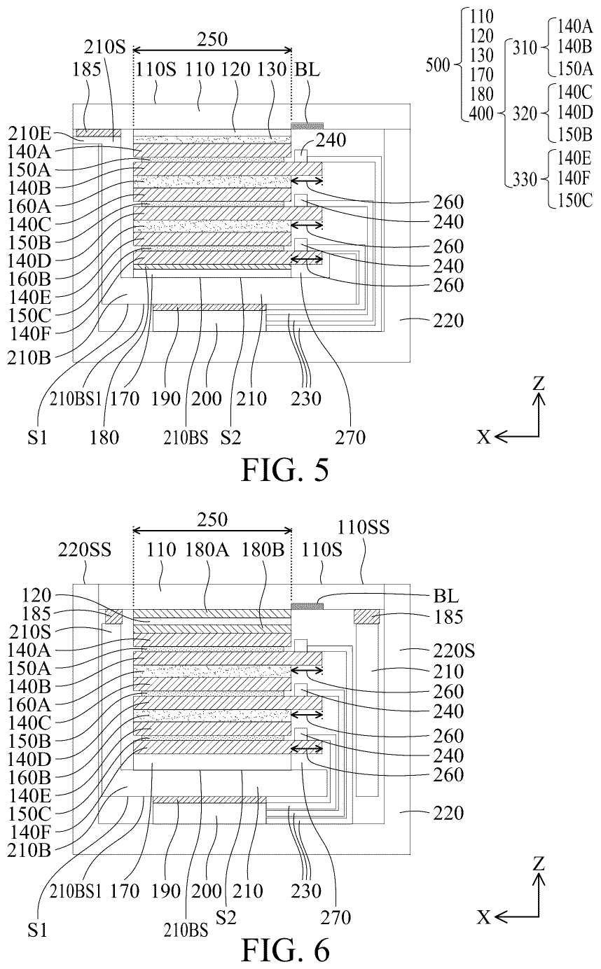

Referring to FIG. 5, FIG. 5 illustrates a schematic cross-sectional view of an electronic device. The embodiment shown in FIG. 5 is different from the embodiment shown in FIG. 2 in that the first frame member 210 may include an extension portion 210E. The extension portion 210E extends, for example, in a direction different from the top view direction Z (the normal direction of the upper surface of the first substrate 140A). The extension portion 210E extends, for example, in the direction X, which is generally perpendicular to the top view direction Z (the normal direction of the upper surface of the first substrate 140A). The present application is not limited thereto. In some embodiments, the second frame member 220 is affixed to the extension portion 210E of the first frame member 210. The second frame member 220 is affixed, for example, through mechanical components (not shown, such as screws or other components) or adhesives. The present application is not limited thereto. In some embodiments, the first frame member 210 (such as the extension portion 210E) may be affixed to the protective substrate 110 through the attachment member 185. The present application is not limited thereto. In some embodiments, the material or design of the attachment member 185 may refer to the description above. The present application is not limited thereto. In some embodiments, in the top view direction Z, the attachment member 185 does not overlap the reflective panel 400.

As shown in FIG. 5, the circuit element 200 may be disposed on the side S1 of the base plate 210B of the first frame member 210 away from the reflective panel 400, and overlap the reflective panel 400. As shown in FIG. 5, a plurality of flexible circuit boards 230 are electrically connected to a plurality of sub-panels (for example, the first sub-panel 310, the second sub-panel 320, and the third sub-panel 330), respectively. A plurality of flexible circuit boards 230 are bent on the side SI of the base plate 210B of the first frame member 210 away from the reflective panel 400 and are electrically connected to the circuit element 200. In some embodiments, the reflective panel 400 is disposed in the receiving area 270 of the first frame member 210, and the protective substrate 110 is disposed on the first frame member 210 and affixed with the first frame member 210. The circuit element 200 may be disposed or affixed on the outside of the first frame member 210 through the attachment component 190 or mechanical components (not shown, such as screws or other components). In some embodiments, the first frame member 210 may be in contact with the display composite element 500 (such as the light-shielding element 170 or other components in the display composite element 500).

Referring to FIG. 6, FIG. 6 illustrates a schematic cross-sectional view of an electronic device. The embodiment shown in FIG. 6 is different from the embodiment shown in FIG. 1 in that the material layer 180A is disposed between the protective substrate 110 and the sensing element 120, and the material layer 180B is disposed between the sensing element 120 and the reflective panel 400. The present application is not limited thereto. By disposing the material layer 180A and/or the material layer 180B between the protective substrate 110 and the reflective panel 400, the acting force applied on the electronic device can be dispersed to reduce the impact of the acting force on the reflective panel 400 and reduce the occurrence of mura.

Although FIG. 6 shows that the electronic device includes material layer 180A and material layer 180B, either material layer 180A or material layer 180B may be selectively removed.

In some embodiments, the material layer 180, material layer 180A, and material layer 180B may include soft materials. The present application is not limited thereto. In some embodiments, the Young's moduli of the material layer 180A and material layer 180B may be between 20 KPa and 350 KPa (20 KPa≤Young's moduli≤350 KPa), between 25 KPa and 320 KPa (25 KPa≤Young's moduli≤320 KPa), between 30 KPa and 310 KPa (30 KPa≤Young's moduli≤310 KPa), between 40 KPa and 280 KPa (40 KPa≤Young's moduli≤280 KPa), or between 45 KPa and 260 KPa (45 KPa≤Young's moduli≤260 KPa). The present application is not limited thereto. In the embodiment shown in FIG. 6, the material layer 180A and/or the material layer 180B may include transparent materials. Through this selection, the impact of the material layer 180A and/or the material layer 180B on the display quality can be reduced.

In some embodiments, the Young's modulus of the material layer 180, material layer 180A, and material layer 180B may be less than the Young's modulus of the protective substrate 110, first substrate 140A, second substrate 140B, third substrate 140C, fourth substrate 140D, fifth substrate 140E, sixth substrate 140F, attachment member 160A, attachment member 160B, and/or light-shielding element 170, respectively. The present application is not limited thereto.

In some embodiments, the configuration of the circuit element 200 of the embodiment shown in FIG. 6 may be similar to the configuration of the circuit element 200 of the embodiment shown in FIG. 4. In specific, the circuit element 200 may be disposed or affixed on the outside of the first frame member 210 through the attachment member 190. In some embodiments, the first frame member 210 may be in contact with the display composite element 500 (for example, the light-shielding element 170 or other elements in the display composite element 500). The present application is not limited thereto. In some embodiments, the material and design of the attachment member 190 may refer to the description above. Similar to FIG. 1, in FIG. 6, the first frame member 210 is affixed to the protective substrate 110 through the attachment member 185. The material and design of the attachment member 185 may refer to the description above. In some embodiments, the projected area (or size) of the protective substrate 110 is, for example, smaller than the projected area (or size) of the second frame member 220. In some embodiments, the protective substrate 110 does not overlap the side frame 220S of the second frame member 220. In some embodiments, the upper surface 110SS of the protective substrate 110 and the upper surface 220SS of the side frame 220S of the second frame member 220 may be substantially aligned. In some embodiments (not shown), the upper surface 110SS of the protective substrate 110 is not aligned with the upper surface 220SS of the side frame 220S of the second frame member 220.

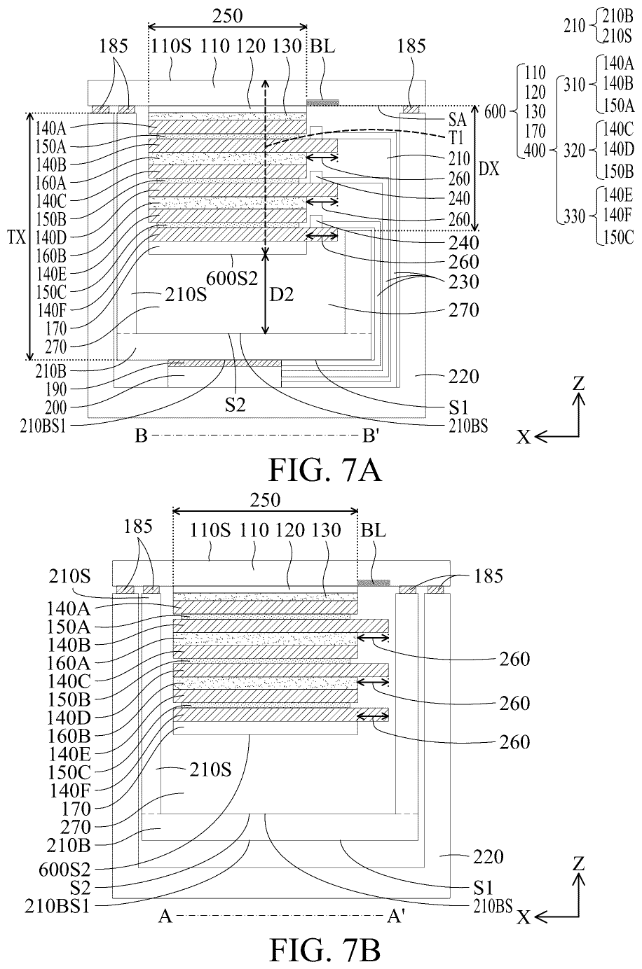

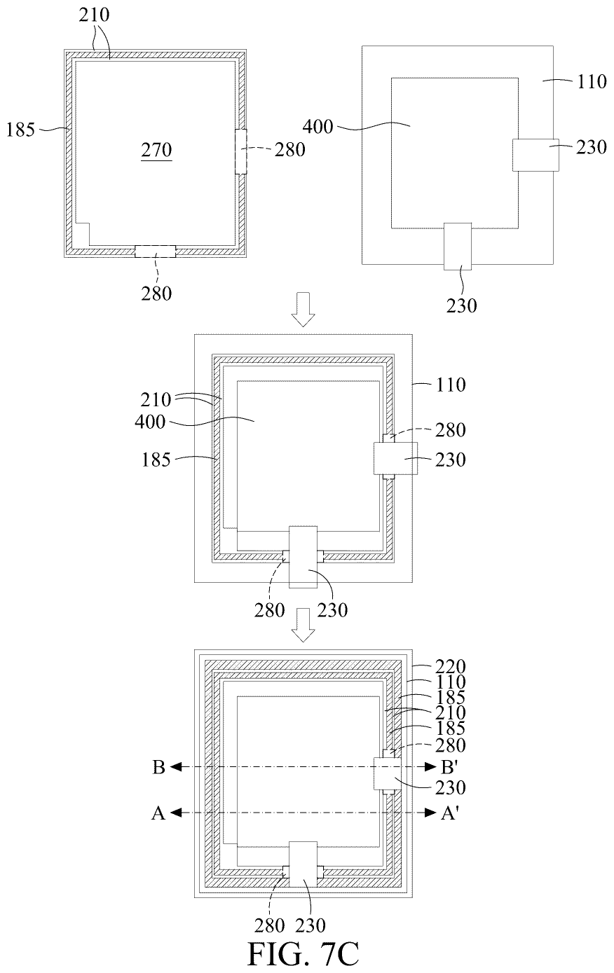

Refer to FIGS. 7A and 7B, FIGS. 7A and 7B illustrate schematic views of an electronic device in different cross-sections. The embodiment shown in FIGS. 7A and 7B is different from the embodiment shown in FIG. 1 in that the display composite element 600 may include the protective substrate 110, sensing component 120, attachment member 130, light-shielding component 170, and/or reflective panel 400, but may optionally not include the material layer 180. The descriptions of the protective substrate 110, sensing element 120, attachment member 130, light-shielding element 170, and/or reflective panel 400 may refer to the description above.

There is a space D2 between the bottom surface 600S2 of the display composite element 600 and the bottom plate 210B (for example, the inner surface 210BS) of the first frame member 210, and the space D2 is greater than 0 mm. A reacting force of pressing can be dispersed through the design of the space D2 to reduce the impact of the reacting force on the reflective panel 400, thereby reducing the occurrence of mura. In some embodiments, the space D2 may be equal to or less than the thickness T1 of the display composite element 600. That is, 0<space D2≤thickness T1. In some embodiments, the space D2 may be equal to or less than 0.8 times the thickness T1 of the display composite element 600. That is, 0<space D2≤0.8×thickness T1. In some embodiments, the space D2 may be equal to or less than 0.6 times the thickness T1 of the display composite element 600. That is, 0<space D2≤0.6×thickness T1. It should be understood that the space D2 depends on the bending resulted from the display composite element 600 in order for the display composite element 600 not to contact the first frame member 210.

As shown in FIGS. 7A and 7B, the first frame member 210 includes a base plate 210B and a side frame 210S. The side frame 210S is connected to the base plate 210B to form a receiving area 270. The reflective panel 400 is disposed in the receiving area 270 of the first frame member 210. In some embodiments, the circuit element 200 is disposed on the side S1 of the base plate 210B away from the reflective panel 400 and overlaps the reflective panel 400. In some embodiments, a plurality of flexible circuit boards 230 are electrically connected to a plurality of sub-panels (such as the first sub-panel 310, the second sub-panel 320, and the third sub-panel 330), respectively. A plurality of flexible circuit boards 230 are bent on the side S1 of the base plate 210B away from the reflective panel 400 and are electrically connected to the circuit element 200. The reflective panel 400 is disposed in the receiving area 270 of the first frame member 210, and the protective substrate 110 is disposed on the first frame member 210 and affixed to the first frame member 210. The circuit element 200 is disposed or affixed on the outside of the first frame member 210 (i.e. the side S1 of the base plate 210B away from the reflective panel 400) through the attachment member 190. The description of the attachment member 190 may refer to the description above.

As shown in FIGS. 7A and 7B, the electronic device further includes the second frame member 220, and the first frame member 210, circuit element 200, and flexible circuit boards 230 are disposed in the second frame member 220. The first frame member 210 and the second frame member 220 may be affixed to the protective substrate 110 through different attachment members 185, respectively. The present application is not limited thereto. In some embodiments, the description of the attachment member 185 may refer to the description above.

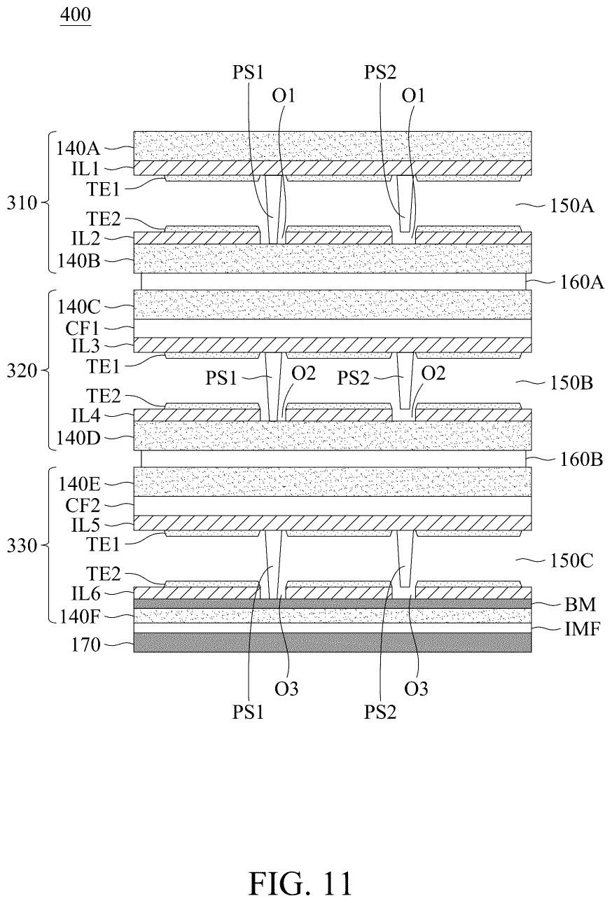

Referring to FIG. 7C, FIG. 7C illustrates a schematic top view of an electronic device. FIG. 7A is the schematic view corresponding to the cross section B-B′ of FIG. 7C, and FIG. 7B is the schematic view corresponding to the cross section A-A′ of FIG. 7C. Referring to FIGS. 7A and 7C, after the protective substrate 110 and the reflective panel 400 are assembled and affixed, they are assembled with the first frame member 210 through the attachment member 185. The first frame member 210 may include a plurality of recessed areas 280. A plurality of recessed areas 280 may be respectively located on the side frames 210S on different sides of the first frame member 210. Different flexible circuit boards 230 (which transmit data signals or scanning signals) may respectively extend from the peripheral circuit bonding area (not shown in FIG. 7C) of each sub-panel to the recessed areas 280 of the first frame member 210. The flexible circuit boards 230 are bent under the base plate 210B of the first frame member 210 to be connected to the circuit element 200. The circuit element 200 is disposed on the side S1 of the base plate 210B away from the reflective panel 400 and overlaps the reflective panel 400. Different sub-panels (the first sub-panel 310, second sub-panel 320, and third sub-panel 330) may be electrically connected to different flexible circuit boards 230 (which transmit data signals or scanning signals). Different flexible circuit boards 230 may respectively receive the data signals or scanning signals transmitted from the circuit element 200, and respectively transmit the data signals or scanning signals to a first electrode TE1 (shown in FIGS. 11-14) and a second electrode TE2 (shown in FIGS. 11-14) in each sub-panel. One ends of the flexible circuit boards 230 are respectively coupled and electrically connected to the sub-panels (the first sub-panel 310, second sub-panel 320, and third sub-panel 330). Subsequently, the above structure (including the protective substrate 110, reflective panel 400, first frame member 210, flexible circuit boards 230, and circuit element 200) is assembled with the second frame member 220. The first frame member 210, circuit element 200, and flexible circuit board 230 may be disposed in the second frame member 220.

In some embodiments (refer to FIG. 7A), in cross-section, the ratio of the depth DX of the recessed area 280 to the thickness TX of the side frame 210S may be between 0.1 and 0.9 (0.1≤DX/TX≤0.9), between 0.2 and 0.8 (0.2≤DX/TX≤0.8), or between 0.3 and 0.7 (0.3≤DX/TX≤0.7). The present application is not limited thereto.

Although FIGS. 7A to 7C are shown as not including the material layer 180, material layer 180A, or material layer 180B, the electronic device shown in FIGS. 7A to 7C may also be additionally provided with the material layer 180, material layer 180A, or material layer 180B. For example, the material layer 180 may be disposed between the light-shielding element 170 and the first frame member 210 (as shown in FIG. 1); the material layer 180 may be disposed between the light-shielding element 170 and the reflective panel 400 (as shown in FIG. 2); the material layer 180A may be disposed between the sensing element 120 and the protective substrate 110 (as shown in FIG. 6); or the material layer 180B may be disposed between the sensing element 120 and the reflective panel 400 (as shown in FIG. 6).

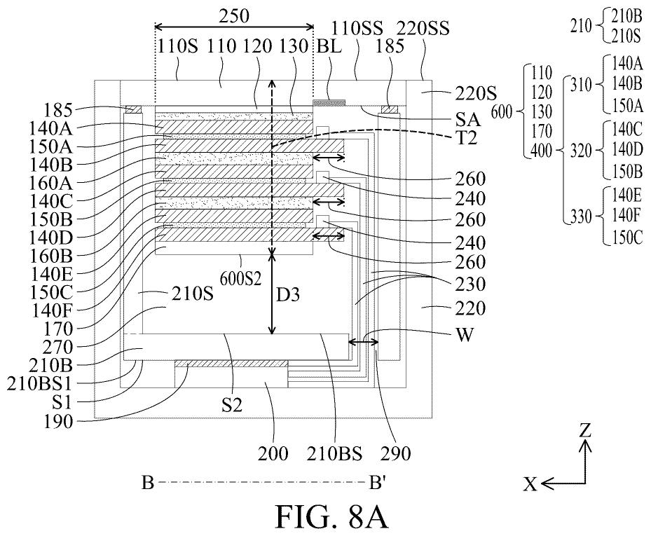

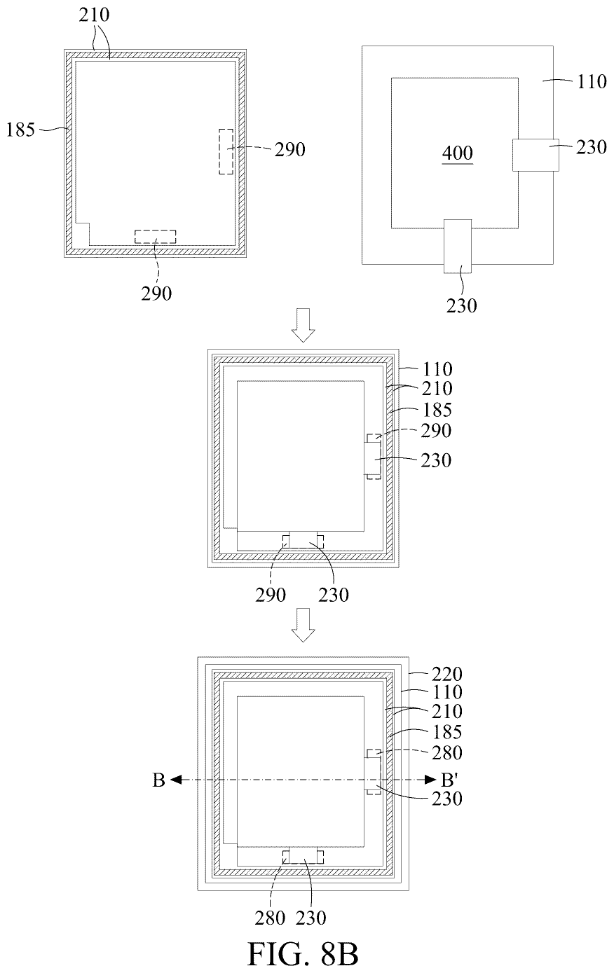

Referring to FIG. 8A, FIG. 8A illustrates a schematic cross-sectional view of an electronic device. Referring to FIG. 8B, FIG. 8B illustrates a schematic top view of an electronic device. FIG. 8A is the schematic view corresponding to section B-B′ in FIG. 8B. The embodiment shown in FIG. 8A is different from the embodiment shown in FIG. 1 in that the display composite element 600 includes the protective substrate 110, sensing element 120, attachment member 130, light-shielding element 170, and reflective panel 400, but does not include the material layer 180. The reflective panel 400 is disposed on the side SA of the protective substrate 110 and includes a plurality of sub-panels (the first sub-panel 310, second sub-panel 320, and third sub-panel 330). In addition, there is a space D3 between the bottom surface 600S2 of the display composite element 600 and the base plate 210B (for example, the inner surface 210BS) of the first frame member 210, and the space D3 is greater than 0 mm. A reacting force of pressing can be dispersed through the space D3 to reduce the impact of the reacting force on the reflective panel 400, thereby reducing the occurrence of mura. In some embodiments, the space D3 may be equal to or less than thickness T2 of the display composite element 600. That is, 0 <space D3≤thickness T2.

As shown in FIG. 8A, the first frame member 210 includes the base plate 210B and the side frame 210S. The side frame 210S is connected to the base plate 210B to form the receiving area 270. The reflective panel 400 is disposed in the receiving area 270 of the first frame member 210. In some embodiments, the circuit element 200 is disposed outside the first frame member 210 through the attachment member 190. The circuit element 200 is disposed on the side S1 of the base plate 210B away from the reflective panel 400 and overlaps the reflective panel 400. In some embodiments, the description of the attachment member 190 may refer to the description above. The first frame member 210 shown in FIGS. 8A and 8B includes, for example, an opening 290. The opening 290 is located in the base plate 210B. A plurality of flexible circuit boards 230 are electrically connected to a plurality of sub-panels (the first sub-panel 310, second sub-panel 320, and third sub-panel 330). A plurality of flexible circuit boards 230 are bent on the side S1 of the base plate 210B away from the reflective panel 400 through the openings 290 of the first frame member 210, and are electrically connected to the circuit element 200. In the cross section, the width W of the opening 290 may be greater than the sum of the thicknesses of the three flexible circuit boards 230.

As shown in FIG. 8A, the first frame member 210 is disposed within the second frame member 220. The protective substrate 110 is disposed on the first frame member 210 and is affixed to the first frame member 210 through the attachment member 185. The description of the attachment member 185 may refer to the description above.

Referring to FIGS. 8A and 8B, after the protective substrate 110 and the reflective panel 400 are assembled and affixed, they are assembled with the first frame member 210 through the attachment member 185. One ends of the flexible circuit boards 230 are electrically connected to different sub-panels (the first sub-panel 310, second sub-panel 320, and third sub-panel 330), respectively. The flexible circuit boards 230 are bent on the side S1 of the base plate 210B away from the reflective panel 400 through the openings 290, and the other ends of the flexible circuit boards 230 are electrically connected to the circuit element 200. Subsequently, the above structure (including the protective substrate 110, reflective panel 400, first frame member 210, and attachment member 185) is assembled to the second frame member 220. In some embodiments, the second frame member 220 and the first frame member 210 may be affixed by mechanical components (such as screws (not shown) or other mechanical components (not shown)). In some embodiments, in the top view direction Z, the attachment member 185 does not overlap the reflective panel 400. In some embodiments, the projected area (or size) of the protective substrate 110 is, for example, smaller than the projected area (or size) of the second frame member 220. In some embodiments, the protective substrate 110 does not overlap the side frame 220S of the second frame member 220. In some embodiments, the upper surface 110SS of the protective substrate 110 and the upper surface 220SS of the side frame 220S of the second frame member 220 may be substantially aligned. In some embodiments (not shown), the upper surface 110SS of the protective substrate 110 is not aligned with the upper surface 220SS of the side frame 220S of the second frame member 220.

In some embodiments (such as FIG. 8A), the first frame member 210, circuit element 200, flexible circuit board 230, and/or the protective substrate 110 are disposed in the second frame member 220.

Although FIGS. 8A and 8B are shown as not including the material layer 180, material layer 180A, or material layer 180B, the electronic device shown in FIGS. 8A and 8B may also be additionally provided with the material layer 180, material layer 180A, or material layer 180B. For example, the material layer 180 may be disposed between the light-shielding element 170 and the first frame member 210 (as shown in FIG. 1); the material layer 180 may be disposed between the light-shielding element 170 and the reflective panel 400 (as shown in FIG. 2); the material layer 180A may be disposed between the sensing element 120 and the protective substrate 110 (as shown in FIG. 6); or the material layer 180B may be disposed between the sensing element 120 and the reflective panel 400 (as shown in FIG. 6).

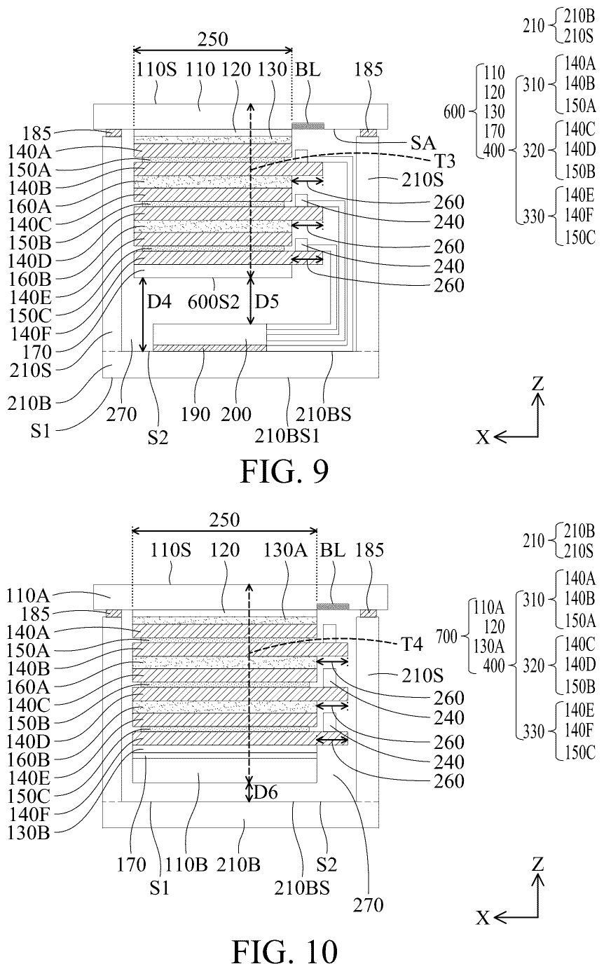

Referring to FIG. 9, FIG. 9 illustrates a schematic cross-sectional view of an electronic device. The embodiment shown in FIG. 9 is different from the embodiment shown in FIG. 1 in that the display composite element 600 includes the protective substrate 110, sensing element 120, attachment member 130, light-shielding element 170, and reflective panel 400, but does not include the material layer 180. The reflective panel 400 is disposed on one side of the protective substrate 110 and includes a plurality of sub-panels (the first sub-panel 310, second sub-panel 320, and third sub-panel 330). In addition, there is a space D4 between the bottom surface 600S2 of the display composite element 600 and the base plate 210B (for example, the inner surface 210BS) of the first frame member 210, and the space D4 is greater than 0 mm. A reacting force of pressing can be dispersed through the space D4 to reduce the impact of the reacting force on the reflective panel 400, thereby reducing the occurrence of mura. There is a space D5 between the bottom surface 600S2 of the display composite element 600 and the top surface of the circuit element 200. The space D5 is greater than 0 mm. The space D4 is larger than the space D5. In some embodiments, the display composite element 600 has a thickness T3, and the space D4 may be less than or equal to the thickness T3 of the display composite element 600. That is, 0<space D4≤thickness T3. The present application is not limited thereto. It should be understood that the space D4 and space D5 depend on the bending resulted from the display composite element 600 in order for the display composite element 600 not to contact the first frame member 210 or circuit element 200.

As shown in FIG. 9, the circuit element 200 is disposed inside the first frame member 210 through the attachment member 190 or mechanical components (such as screws). The present application is not limited thereto. The circuit element 200 is disposed on the side S2 of the base plate 210B adjacent to the reflective panel 400, and overlaps the reflective panel 400. One ends of the flexible circuit boards 230 are electrically connected to a plurality of sub-panels (the first sub-panel 310, second sub-panel 320, and third sub-panel 330), respectively. A plurality of flexible circuit boards 230 are bent under the reflective panel 400, and the other ends of the flexible circuit boards 230 are electrically connected to the circuit element 200, respectively.

Although FIG. 9 is shown as not including the material layer 180, material layer 180A, or material layer 180B, the electronic device shown in FIG. 9 may also be additionally provided with the material layer 180, material layer 180A, or material layer 180B. For example, the material layer 180 may be disposed between the light-shielding element 170 and the first frame member 210 (as shown in FIG. 1); the material layer 180 may be disposed between the light-shielding element 170 and the reflective panel 400 (as shown in FIG. 2); the material layer 180A may be disposed between the sensing element 120 and the protective substrate 110 (as shown in FIG. 6); or the material layer 180B may be disposed between the sensing element 120 and the reflective panel 400 (as shown in FIG. 6).

Referring to FIG. 10, FIG. 10 illustrates a schematic cross-sectional view of an electronic device. In some embodiments, the electronic device includes a display composite element 700. The display composite element 700 includes the first protective substrate 110A, sensing component 120, first attachment member 130A, and/or reflective panel 400. In addition, the electronic device further includes a second protective substrate 110B. The second protective substrate 110B is disposed between the reflective panel 400 and the first frame member 210 (for example, the base plate 210B). The second attachment member 130B and/or the light-shielding element 170 is disposed between the second protective substrate 110B and the reflective panel 400. The present application is not limited thereto. The area (or size) of the second protective substrate 110B may be smaller than the area (or size) of the first protective substrate 110A. In some embodiments (not shown), the second protective substrate 110B may, for example, selectively extend from the active area 250 (refer to the description above) of the reflective panel 400 to the peripheral circuit bonding area 260 (refer to the description above) of the reflective panel 400.

Referring to FIG. 10, in some embodiments, the light-shielding element 170 may be disposed between the second attachment member 130B and the second protective substrate 110B. The present application is not limited thereto. In other embodiments (not shown), the light-shielding element 170 may be disposed between the reflective panel 400 and the second attachment member 130B. The present application is not limited thereto. The electronic device includes the first frame member 210, and the first frame member 210 is affixed to the first protective substrate 110A through the attachment member 185. In some embodiments, in the normal direction of the base plate 210B (or the top view direction Z), the display composite element 700 has a thickness T4. There is a space D6 between the bottom surface (for example, the bottom surface of the second protective substrate 110B) of the display composite element 700 and the base plate 210B (for example, the inner surface 210BS) of the first frame member 210. The space D6 is greater than 0 mm. In this embodiment, a reacting force of pressing can be dispersed through the second protective substrate 110B, so as to reduce the impact of the reacting force on the reflective panel 400, thereby reducing the occurrence of mura.

Referring to FIG. 10, in some embodiments, the materials of the sensing element 120, the reflective panel 400, and the attachment member 185 may refer to the description with FIG. 1. Therefore, it is not repeated herein. In some embodiments, the first protective substrate 110A and the second protective substrate 110B may each include polymethylmethacrylate (PMMA), polycarbonate (PC), other suitable materials, or a combination thereof. The present application is not limited thereto. The Young's modulus of each of the first protective substrate 110A and the second protective substrate 110B may be between 1 GPa and 80 GPa (1 GPa≤Young's modulus≤80 GPa), between 2 GPa and 76 GPa (2 GPa≤Young's modulus≤76 GPa), or between 3 GPa and 72 GPa (3 GPa≤Young's modulus≤72 GPa). The thickness of each of the first protective substrate 110A and the second protective substrate 110B may be between 0.2 mm to 2.5 mm (0.2 mm≤thickness≤2.5 mm), between 0.2 mm to 2.3 mm (0.2 mm≤thickness≤2.3 mm), between 0.4 mm to 2 mm (0.4 mm≤thickness≤2 mm), between 0.5 mm and 1.8 mm (0.5 mm≤thickness≤1.8 mm), or between 0.6 mm and 1.5 mm (0.6 mm≤thickness≤1.5 mm). The present application is not limited thereto. In some embodiments, the material and/or thickness of the first protective substrate 110A may be the same as the second protective substrate 110B. In other embodiments, the material and/or thickness of the first protective substrate 110A may be different from the second protective substrate 110B.

Referring to FIG. 10, the attachment member 130A and the attachment member 130B may include optical clear adhesive (OCA), optical clear resin (OCR), other suitable materials, or a combination thereof. The present application is not limited thereto. In some embodiments, the material or thickness of the attachment member 130A may be the same as the attachment member 130B. In other embodiments, the material or thickness of the attachment member 130A may be different from the attachment member 130B. In some embodiments, the light-shielding element 170 may include a black matrix (BM), ink, or other suitable light-shielding materials.

In some embodiments (not shown), the light-shielding element 170 may be disposed on the surface of the sixth substrate 140F adjacent to the first frame member 210 and be in contact with it. The second protective substrate 110B is affixed to the light-shielding element 170 through the second attachment member 130B. The second attachment member 130B is disposed between the light-shielding element 170 and the second protective substrate 110B. In some embodiments (not shown), the light-shielding element 170 may be disposed between the third liquid crystal layer 150C and the sixth substrate 140F.

Referring to FIGS. 11-14, FIGS. 11-14 illustrate partial and schematic cross-sectional views of electronic devices, respectively. For example, the stacks of the reflective panels 400 are shown in different embodiments.

Referring to FIG. 11, the reflective panel 400 includes a plurality of sub-panels, such as the first sub-panel 310, second sub-panel 320, and third sub-panel 330. The number of sub-panels included in the reflective panel 400 may be adjusted according to needs. The first sub-panel 310 includes the first substrate 140A, second substrate 140B, and first liquid crystal layer 150A disposed between the first substrate 140A and the second substrate 140B. The second sub-panel 320 includes the third substrate 140C, fourth substrate 140D, and second liquid crystal layer 150B disposed between the third substrate 140C and the fourth substrate 140D. The third sub-panel 330 includes the fifth substrate 140E, sixth substrate 140F, and third liquid crystal layer 150C disposed between the fifth substrate 140E and the sixth substrate 140F. The first sub-panel 310 and the second sub-panel 320 can be affixed through the attachment member 160A, and the second sub-panel 320 and the third sub-panel 330 can be affixed through the attachment member 160B. Referring to FIG. 11, the first sub-panel 310, second sub-panel 320, and/or third sub-panel 330 respectively include a plurality of first electrodes TE1 and a plurality of second electrodes TE2, respectively. For example, a plurality of first electrodes TE1 are arranged in sequence along a first direction, and a plurality of second electrodes TE2 are arranged in sequence along a second direction. The first direction is substantially perpendicular to the second direction. A plurality of first electrodes TE1 in the first sub-panel 310 are disposed between the first substrate 140A and the first liquid crystal layer 150A, and a plurality of second electrodes TE2 in the first sub-panel 310 are disposed between the second substrate 140B and the first liquid crystal layer 150A. An insulating layer IL1 is disposed between the first substrate 140A and a plurality of first electrodes TE1, and the insulating layer IL1 may selectively have the characteristics of being transparent and reducing ultraviolet light. The present application is not limited thereto. An insulating layer IL2 is disposed between the second substrate 140B and a plurality of second electrodes TE2, and the insulating layer IL2 includes, for example, a plurality of openings O1. A plurality of openings O1 may, for example, expose the stack below the insulating layer IL2 (such as the second substrate 140B). The present application is not limited thereto. The first sub-panel 310 further includes a plurality of first spacers PS1 and a plurality of second spacers PS2. The thickness of the first spacers PS1 is greater than the thickness of the second spacers PS2. In the cross-section, the first spacer PS1 and the second spacer PS2 may respectively overlap different openings O1 of the insulating layer IL2. One surface of each of the first spacer PS1 and the second spacer PS2 may be in contact with the insulating layer IL1. The other surface of the first spacer PS1 may be selectively in contact with the stack below the insulating layer IL2 (such as the second substrate 140B). The other surface of the second spacer PS2 may be selectively not in contact with the stack below the insulating layer IL2 (such as the second substrate 140B). The present application is not limited thereto. Through this design, the chance of short circuit occurring between adjacent second electrodes TE2 can be reduced. For example, the first spacer PS1 and the second spacer PS2 do not contact or overlap the first electrode TE1 and the second electrode TE2. Through this design, the impact of the first spacer PS1 and the second spacer PS2 on the pixel display can be reduced.

Similarly, referring to FIG. 11, a plurality of first electrodes TE1 in the second sub-panel 320 are disposed between the third substrate 140C and the second liquid crystal layer 150B, and a plurality of second electrodes TE2 in the second sub-panel 320 are disposed between the fourth substrate 140D and the second liquid crystal layer 150B. An insulating layer IL3 is disposed between the third substrate 140C and a plurality of first electrodes TE1. An insulating layer IL4 is disposed between the fourth substrate 140D and a plurality of second electrodes TE2, and the insulating layer IL4 includes, for example, a plurality of openings O2. A plurality of openings O2 may, for example, expose the stack below the insulating layer IL4 (such as the fourth substrate 140D). The present application is not limited thereto. The second sub-panel 320 further includes a plurality of first spacers PS1 and a plurality of second spacers PS2. The thickness of the first spacers PS1 is greater than the thickness of the second spacers PS2. In the cross-section, the first spacer PS1 and the second spacer PS2 may respectively overlap different openings O2 of the insulating layer IL4. One surface of each of the first spacer PS1 and the second spacer PS2 may be in contact with the insulating layer IL3. The other surface of the first spacer PS1 may be selectively in contact with the stack below the insulating layer IL4 (such as the fourth substrate 140D). The other surface of the second spacer PS2 may be selectively not in contact with the stack below the insulating layer IL4 (such as the fourth substrate 140D). The present application is not limited thereto. Through this design, the chance of short circuit occurring between adjacent second electrodes TE2 can be reduced. For example, the first spacer PS1 and the second spacer PS2 do not contact or overlap the first electrode TE1 and the second electrode TE2. Through this design, the impact of the first spacer PS1 and the second spacer PS2 on the pixel display can be reduced. The second sub-panel 320 may optionally include a first filter layer CF1. When the first liquid crystal layer 150A and the second liquid crystal layer 150B reflect blue and green light respectively, the first filter layer CF1 may, for example, be a yellow filter layer. The present application is not limited thereto. The first filter layer CF1 may be disposed between the third substrate 140C and the insulating layer IL3. The present application is not limited thereto.

Similarly, referring to FIG. 11, a plurality of first electrodes TE1 in the third sub-panel 330 are disposed between the fifth substrate 140E and the third liquid crystal layer 150C, and a plurality of second electrodes TE2 in the third sub-panel 330 are disposed between the sixth substrate 140F and the third liquid crystal layer 150C. An insulating layer IL5 is disposed between the fifth substrate 140E and a plurality of first electrodes TE1. An insulating layer IL6 is disposed between the sixth substrate 140F and a plurality of second electrodes TE2, and the insulating layer IL6 includes, for example, a plurality of openings O3. A plurality of openings O3 may, for example, expose the stack below the insulating layer IL6 (such as the sixth substrate 140F or light-shielding layer BM (such as a black photoresist layer)). The present application is not limited thereto. The third sub-panel 330 further includes a plurality of first spacers PS1 and a plurality of second spacers PS2. The thickness of the first spacers PS1 is greater than the thickness of the second spacers PS2. In the cross-section, the first spacer PS1 and the second spacer PS2 may respectively overlap different openings O3 of the insulating layer IL6. One surface of each of the first spacer PS1 and the second spacer PS2 may be in contact with the insulating layer IL5. The other surface of the first spacer PS1 may be selectively in contact with the sixth substrate 140F or light-shielding layer BM. The other surface of the second spacer PS2 may be selectively not in contact with the sixth substrate 140F or light-shielding layer BM. The present application is not limited thereto. Through this design, the chance of short circuit occurring between adjacent second electrodes TE2 can be reduced. For example, the first spacer PS1 and the second spacer PS2 do not contact or overlap the first electrode TE1 and the second electrode TE2. Through this design, the impact of the first spacer PS1 and the second spacer PS2 on the pixel display can be reduced. The third sub-panel 330 may optionally include a second filter layer CF2. When the second liquid crystal layer 150B and the third liquid crystal layer 150C reflect green and red light respectively, the second filter layer CF2 may, for example, be a red filter layer. The present application is not limited thereto. The second filter layer CF2 may be disposed between the fifth substrate 140E and the insulating layer IL5. The present application is not limited thereto.

Referring to FIG. 11, the light-shielding element 170 is, for example, disposed on the side of the third sub-panel 330 away from the second sub-panel 320. A refractive index matching layer IMF may be optionally added between the light-shielding element 170 and the third sub-panel 330 to reduce light reflection. The present application is not limited thereto. Referring to FIG. 11, the light-shielding layer BM (such as a black photoresist layer) may be selectively disposed in the third sub-panel 330, for example, between the sixth substrate 140F and the third liquid crystal layer 150C. It should be noted that although the electronic device shown in FIG. 11 includes both the light-shielding element 170 and the light-shielding layer BM, in other embodiments, one of the light-shielding elements 170 and the light-shielding layer BM may be used.

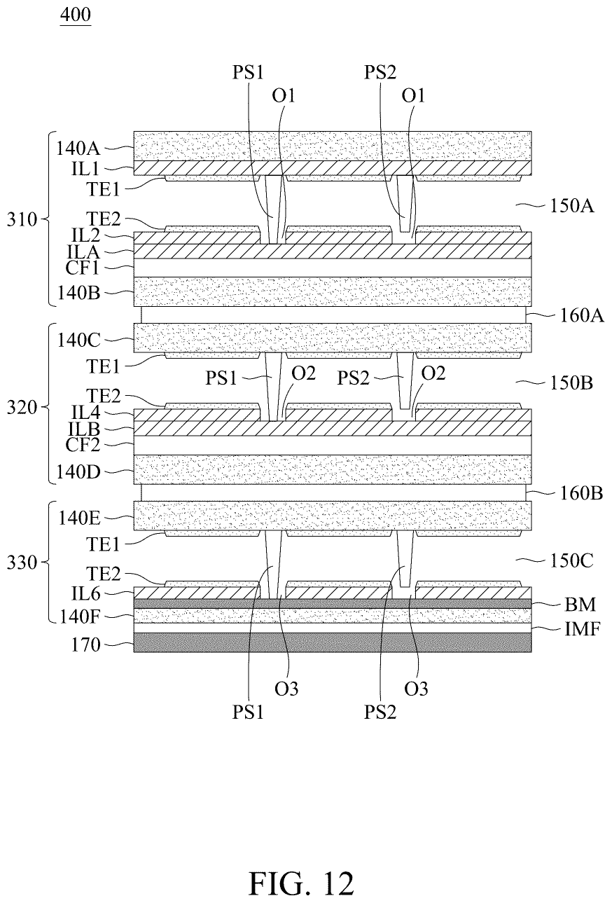

Referring to FIG. 12, the stack of the first sub-panel 310, second sub-panel 320, and/or third sub-panel 330 included in the reflective panel 400 is similar to that shown in FIG. 11. The main difference is that the first filter layer CF1 and second filter layer CF2 are disposed in different positions. As shown in FIG. 11, for example, the first filter layer CF1 may be disposed in the second sub-panel 320, and the second filter layer CF2 may be disposed in the third sub-panel 330. As shown in FIG. 12, for example, the first filter layer CF1 may be disposed in the first sub-panel 310, and the second filter layer CF2 may be disposed in the second sub-panel 320. In specific, as shown in FIG. 12, for example, the first filter layer CF1 may be disposed between the second substrate 140B and the first liquid crystal layer 150A, and the second filter layer CF2 may be disposed between the fourth substrate 140D and the second liquid crystal layer 150B. The present application is not limited thereto. As shown in FIG. 12, the first sub-panel 310 may further include an insulating layer ILA disposed between the insulating layer IL2 and the first filter layer CF1. A plurality of openings O1 of the insulating layer IL2 may, for example, expose the stack below the insulating layer IL2 (such as the insulating layer ILA). One surface of each of the first spacer PS1 and the second spacer PS2 in the first sub-panel 310 may be in contact with the insulating layer IL1. The other surface of the first spacer PS1 may be selectively in contact with the insulating layer ILA. The other surface of the second spacer PS2 may be selectively not in contact with the insulating layer ILA. The present application is not limited thereto. The insulating layer IL3 may be optionally omitted from the first sub-panel 310.

Similarly, as shown in FIG. 12, the second sub-panel 320 may further include an insulating layer ILB disposed between the insulating layer IL4 and the second filter layer CF2. A plurality of openings O2 of the insulating layer IL4 may, for example, expose the stack below the insulating layer IL4 (such as the insulating layer ILB). One surface of each of the first spacer PS1 and the second spacer PS2 in the second sub-panel 320 may be in contact with the third substrate 140C. The other surface of the first spacer PS1 may be selectively in contact with the insulating layer ILB. The other surface of the second spacer PS2 may be selectively not in contact with the insulating layer ILB. The present application is not limited thereto. The insulating layer IL5 may be optionally omitted from the third sub-panel 330.

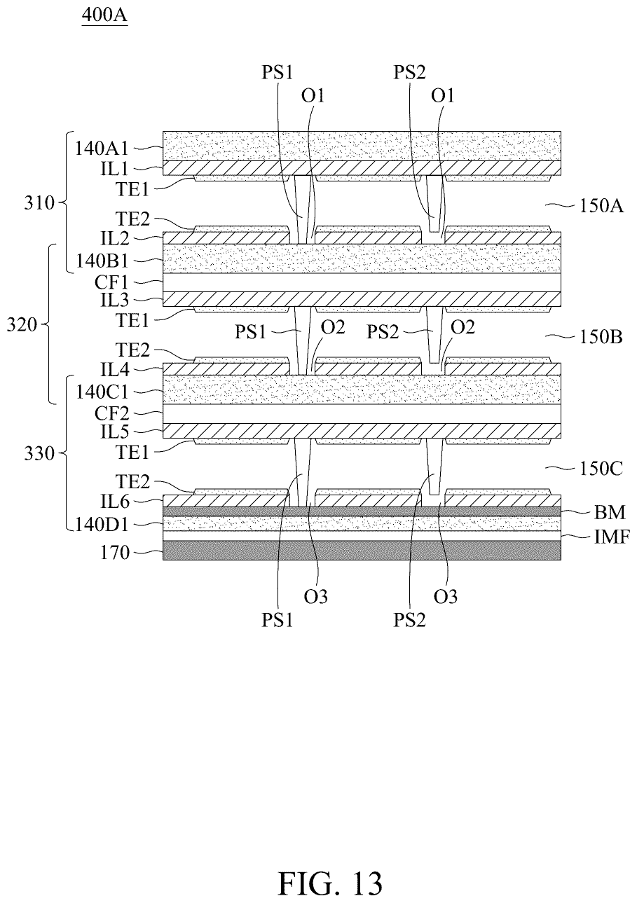

Referring to FIG. 13, a reflective panel 400A includes a plurality of sub-panels, such as the first sub-panel 310, second sub-panel 320, and/or third sub-panel 330. The number of sub-panels included in the reflective panel 400A may be adjusted according to needs. The main difference between the reflective panel 400A in FIG. 13 and the reflective panel 400 in FIG. 11 is that the first sub-panel 310 and the second sub-panel 320 of the reflective panel 400A may share the substrate 140B1, and the second sub-panel 320 and the third sub-panels 330 may share the substrate 140C1. In specific, the reflective panel 400A includes a substrate 140A1, substrate 140B1, substrate 140C1, and substrate 140D1. The first liquid crystal layer 150A is disposed between the substrate 140A1 and the substrate 140B1, the second liquid crystal layer 150B is disposed between the substrate 140B1 and the substrate 140C1, and the third liquid crystal layer 150C is disposed between the substrate 140C1 and the substrate 140D1. In this embodiment, for example, the attachment members 160A and 160B may be omitted. Similarly, the first sub-panel 310, second sub-panel 320, and/or third sub-panel 330 respectively include a plurality of first electrodes TE1 and a plurality of second electrodes TE2, respectively. For example, a plurality of first electrodes TE1 are arranged in sequence along a first direction, and a plurality of second electrodes TE2 are arranged in sequence along a second direction. The first direction is substantially perpendicular to the second direction. The insulating layer IL1 in the first sub-panel 310 is disposed between the substrate 140A1 and a plurality of first electrodes TE1, and the insulating layer IL1 may selectively have the characteristics of being transparent and reducing ultraviolet light. The present application is not limited thereto. The insulating layer IL2 in the first sub-panel 310 is disposed between the substrate 140B1 and a plurality of second electrodes TE2, and the insulating layer IL2 includes, for example, a plurality of openings O1. A plurality of openings O1 may, for example, expose the stack below the insulating layer IL2 (such as the second substrate 140B1). In the cross-section, the first spacer PS1 and the second spacer PS2 in the first sub-panel 310 may respectively overlap different openings O1 of the insulating layer IL2. One surface of each of the first spacer PS1 and the second spacer PS2 may be in contact with the insulating layer IL1. The other surface of the first spacer PS1 may be selectively in contact with the substrate 140B1. The other surface of the second spacer PS2 may be selectively not in contact with the substrate 140B1. The present application is not limited thereto. Through this design, the chance of short circuit occurring between adjacent second electrodes TE2 can be reduced.

Similarly, referring to FIG. 13, the insulating layer IL3 in the second sub-panel 320 is disposed between the substrate 140B1 and a plurality of first electrodes TE1. The insulating layer IL4 in the second sub-panel 320 is disposed between the substrate 140C1 and a plurality of second electrodes TE2, and the insulating layer IL4 includes, for example, a plurality of openings O2. A plurality of openings O2 may, for example, expose the stack below the insulating layer IL4 (such as the substrate 140C1). In the cross-section, the first spacer PS1 and the second spacer PS2 in the second sub-panel 320 may respectively overlap different openings O2 of the insulating layer IL4. One surface of each of the first spacer PS1 and the second spacer PS2 may be in contact with the insulating layer IL3. The other surface of the first spacer PS1 may be selectively in contact with the substrate 140C1. The other surface of the second spacer PS2 may be selectively not in contact with the substrate 140C1. The present application is not limited thereto. Through this design, the chance of short circuit occurring between adjacent second electrodes TE2 can be reduced. The second sub-panel 320 may optionally include the first filter layer CF1. When the first liquid crystal layer 150A and the second liquid crystal layer 150B reflect blue and green light respectively, the first filter layer CF1 may, for example, be a yellow filter layer. The present application is not limited thereto. The first filter layer CF1 may be disposed between the substrate 140B1 and the insulating layer IL3. The present application is not limited thereto.

Similarly, referring to FIG. 13, the insulating layer IL5 in the third sub-panel 330 is disposed between the substrate 140C1 and a plurality of first electrodes TE1. The insulating layer IL6 in the third sub-panel 330 is disposed between the substrate 140D1 and a plurality of second electrodes TE2, and the insulating layer IL6 includes, for example, a plurality of openings O3. A plurality of openings O3 may, for example, expose the stack below the insulating layer IL6 (such as the substrate 140D1 or light-shielding layer BM). The light-shielding layer BM (such as a black photoresist layer) may be selectively disposed in the third sub-panel 330, for example, between the substrate 140D1 and the third liquid crystal layer 150C. In the cross-section, the first spacer PS1 and the second spacer PS2 in the third sub-panel 330 may respectively overlap different openings O3 of the insulating layer IL6. One surface of each of the first spacer PS1 and the second spacer PS2 may be in contact with the insulating layer IL5. The other surface of the first spacer PS1 may be selectively in contact with the substrate 140D1 or light-shielding layer BM. The other surface of the second spacer PS2 may be selectively not in contact with the substrate 140D1 or light-shielding layer BM. The present application is not limited thereto. Through this design, the chance of short circuit occurring between adjacent second electrodes TE2 can be reduced. The third sub-panel 330 may optionally include the second filter layer CF2. When the second liquid crystal layer 150B and the third liquid crystal layer 150C reflect green and red light respectively, the second filter layer CF2 may, for example, be a red filter layer. The present application is not limited thereto. The second filter layer CF2 may be disposed between the substrate 140C1 and the insulating layer IL5. The present application is not limited thereto. Referring to FIG. 13, the light-shielding element 170 is, for example, disposed on the side of the third sub-panel 330 away from the second sub-panel 320. The refractive index matching layer IMF may be optionally added between the light-shielding element 170 and the third sub-panel 330. The present application is not limited thereto. Although the electronic device shown in FIG. 13 includes both the light-shielding element 170 and the light-shielding layer BM, in other embodiments, one of the light-shielding elements 170 and the light-shielding layer BM may be used.

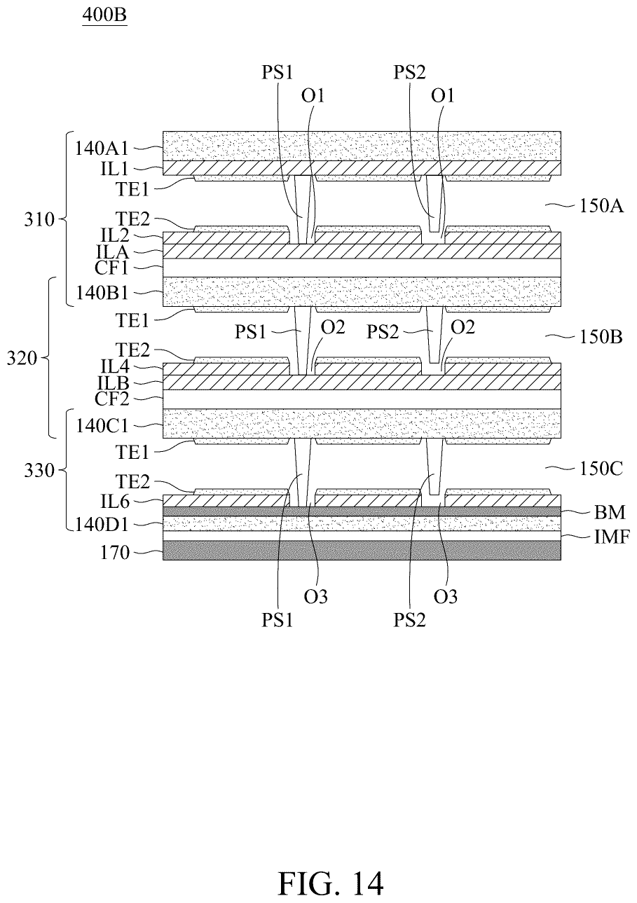

Referring to FIG. 14, the stack of the first sub-panel 310, second sub-panel 320, and/or third sub-panel 330 included in a reflective panel 400B is similar to that in FIG. 13. The main difference is that the first filter layer CF1 and second filter layer CF2 are disposed in different positions. As shown in FIG. 13, for example, the first filter layer CF1 may be disposed in the second sub-panel 320, and the second filter layer CF2 may be disposed in the third sub-panel 330. As shown in FIG. 14, for example, the first filter layer CF1 may be disposed in the first sub-panel 310, and the second filter layer CF2 may be disposed in the second sub-panel 320. In specific, as shown in FIG. 14, for example, the first filter layer CF1 may be disposed between the substrate 140B and the first liquid crystal layer 150A, and the second filter layer CF2 may be disposed between the substrate 140C1 and the second liquid crystal layer 150B. The present application is not limited thereto. As shown in FIG. 14, the first sub-panel 310 may further include the insulating layer ILA disposed between the insulating layer IL2 and the first filter layer CF1. A plurality of openings O1 of the insulating layer IL2 may, for example, expose the stack below the insulating layer IL2 (such as the insulating layer ILA). One surface of each of the first spacer PS1 and the second spacer PS2 in the first sub-panel 310 may be in contact with the insulating layer IL1. The other surface of the first spacer PS1 may be selectively in contact with the insulating layer ILA. The other surface of the second spacer PS2 may be selectively not in contact with the insulating layer ILA. The present application is not limited thereto. The insulating layer IL3 may be optionally omitted from the first sub-panel 310.

Similarly, as shown in FIG. 14 the second sub-panel 320 may further include the insulating layer ILB disposed between the insulating layer IL4 and the second filter layer CF2. A plurality of openings 02 of the insulating layer IL4 may, for example, expose the stack below the insulating layer IL4 (such as the insulating layer ILB). One surface of each of the first spacer PS1 and the second spacer PS2 in the second sub-panel 320 may be in contact with the substrate 140B1. The other surface of the first spacer PS1 may be selectively in contact with the insulating layer ILB. The other surface of the second spacer PS2 may be selectively not in contact with the insulating layer ILB. The present application is not limited thereto. The insulating layer IL5 may be optionally omitted from the third sub-panel 330. It should be noted that the reflective panels in FIGS. 11-14 may be used in the stack in FIGS. 1-10.

To sum up, in some embodiments, by disposing the material layer on the side of the reflective panel away from the protective substrate, the reacting force of pressing can be dispersed to reduce the impact of the reacting force on the reflective panel, thereby reducing the occurrence of mura. In other embodiments, by disposing the material layer between the reflective panel and the protective substrate (on the side of the reflective panel adjacent to the protective substrate), the acting force of pressing can be dispersed to reduce the impact of the acting force on the reflective panel, thereby reducing the occurrence of mura. In some embodiments, by placing the space greater than 0 mm between the display composite element and the base plate of the frame member, the reacting force of pressing can be dispersed to reduce the impact of the reacting force on the reflective panel, thereby reducing the occurrence of mura.

Although some embodiments of the present disclosure and their advantages have been described in detail, it should be understood that various changes, substitutions and alterations can be made herein without departing from the spirit and scope of the present disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a reflective panel;
a light-shielding element disposed on a side of the reflective panel away from a viewing side of the electronic device; and
a material layer disposed on the side of the reflective panel away from the viewing side of the electronic device,
wherein a Young's modulus of the material layer is less than a Young's modulus of the light-shielding element.

2. The electronic device of claim 1, wherein the material layer is disposed between the reflective panel and the light-shielding element.

3. The electronic device of claim 1, wherein the light-shielding element is disposed between the reflective panel and the material layer.

4. The electronic device of claim 1, wherein the Young's modulus of the material layer is from 20 KPa to 350 KPa.

5. The electronic device of claim 3, wherein in a top view of the electronic device, the material layer overlaps an active area and a peripheral circuit bonding area of the reflective panel.

6. The electronic device of claim 1, wherein the reflective panel comprises:
a first sub-panel;
a second sub-panel; and
an attachment member disposed between the first sub-panel and the second sub-panel, wherein the Young's modulus of the material layer is less than a Young's modulus of the attachment member.

7. The electronic device of claim 6, wherein the first sub-panel comprises a first substrate and a second substrate, the second sub-panel comprises a third substrate and a fourth substrate, and the Young's modulus of the material layer is less than the Young's moduli of the first substrate, the second substrate, the third, and the fourth substrate.

8. The electronic device of claim 1, further comprising a protective substrate disposed on the reflective panel.

9. The electronic device of claim 8, wherein the Young's modulus of the material layer is less than a Young's modulus of the protective substrate.

10. The electronic device of claim 1, wherein the material layer comprises sponge, foam, soft plastic, or a combination thereof.

11. An electronic device, comprising:
a first frame member comprising a base plate and a side frame, wherein the side frame is connected to the base plate to form a placement area; and
a display composite element comprising:
a protective substrate; and
a reflective panel disposed on a side of the protective substrate and comprising a plurality of sub-panels,
wherein the reflective panel is disposed in the placement area of the first frame member,
the protective substrate is disposed on the first frame member and affixed to the first frame member, and
there is a first space greater than 0 mm between the display composite element and the base plate.

12. The electronic device of claim 11, further comprising:
a circuit element disposed on a side of the base plate away from the reflective panel, wherein the circuit element overlaps the reflective panel; and
a plurality of flexible circuit boards, each of which is electrically connected to a respective sub-panel, wherein the plurality of flexible circuit boards are bent on the side of the base plate away from the reflective panel and are electrically connected to the circuit element.

13. The electronic device of claim 12, further comprising a second frame member, wherein the first frame member, the circuit element, and the plurality of flexible circuit boards are disposed in the second frame member.

14. The electronic device of claim 13, wherein the circuit element and the plurality of flexible circuit boards are disposed between the first frame member and the second frame member.

15. The electronic device of claim 13, wherein the first frame member comprises an extension portion disposed between the protective substrate and the second frame member.

16. The electronic device of claim 11, further comprising:
a circuit element disposed on a side of the base plate close to the reflective panel, wherein the circuit element overlaps the reflective panel; and
a plurality of flexible circuit boards, each of which is electrically connected to a respective sub-panel, wherein the plurality of flexible circuit boards are bent under the reflective panel and are electrically connected to the circuit element.

17. The electronic device of claim 16, wherein the display composite element is in contact with the circuit element.

18. The electronic device of claim 16, wherein the display composite element is not in contact with the circuit element.

19. The electronic device of claim 18, wherein there is a second space between the display composite element and the circuit element, and the second space is smaller than the first space.

20. The electronic device of claim 11, wherein the display composite element has a thickness, and the first space is smaller than or equal to the thickness.
